(19) United States
(12) Patent Application Publication
(10) Pub. No.: US 2023/0223337 A1
(43) Pub. Date: Jul. 13, 2023

(54) MIDDLE OF THE LINE HEATER AND METHODS

(71) Applicant: GlobalFoundries U.S. Inc., Malta, NY (US)

(72) Inventors: Mark D. Levy, Williston, VT (US); Fuad H. Al-Amoody, Colchester, VT (US); Siva P. Adusumilli, South Burlington, VT (US); Spencer H. Porter, Colchester, VT (US); Ephrem Gebreselasie, South Burlington, VT (US); Rajendran Krishnasamy, Essex Junction, VT (US)

(73) Assignee: GlobalFoundries U.S. Inc., Malta, NY (US)

(21) Appl. No.: 17/572,681

(22) Filed: Jan. 11, 2022

(51) Int. Cl. H01L 23/525; H01L 21/768; H01L 23/36; H01L 23/34; H01L 23/522

(52) U.S. Cl. CPC H01L 23/5256; H01L 21/76877; H01L 23/36; H01L 23/345; H01L 21/76832; H01L 23/5226; H01L 21/76816

(57) ABSTRACT

A semiconductor structure includes a semiconductor device (e.g., an e-fuse or photonic device) and a metallic heating element adjacent thereto. The heating element has a lower portion within a middle of the line (MOL) dielectric layer adjacent to the semiconductor device and an upper portion with a tapered top end that extends into a back end of the line (BEOL) dielectric layer. A method of forming the semiconductor structure includes forming a cavity such that it has both a lower section, which extends from a top surface of a MOL dielectric layer downward toward a semiconductor device, and an upper section, which extends from the top surface of the MOL dielectric layer upward and which is capped by an area of a BEOL dielectric layer having a concave bottom surface. A metallic fill material can then be deposited into the cavity (e.g., through via openings) to form the heating element.

### BACKGROUND

### Field of the Invention

The present invention relates to on-chip heaters and, more particularly, to embodiments of a semiconductor structure including a heater adjacent to a semiconductor device, to embodiments of a method of forming the semiconductor structure, and to embodiments of a method of employing the heater to heat the semiconductor device.

### Description of Related Art

Chip designs may include one or more back end of the line (BEOL) heaters for heating one or more front end of the line (FEOL) semiconductor devices. However, given the separation distance between the BEOL and FEOL levels on a chip, meeting the thermal requirements of the semiconductor device(s) can be difficult. Middle of the line (MOL) polysilicon heaters have been developed that can be placed closer to the FEOL semiconductor devices, but these polysilicon heaters tend to exhibit reliability issues.

### SUMMARY

In view of the foregoing, disclosed herein are embodiments of a semiconductor structure including a semiconductor device (e.g., an electronic fuse (e-fuse) or some other type of device that can benefit from thermal tuning) and a metallic heating element adjacent thereto. The metallic heating element can have a lower portion, which is within a middle of the line (MOL) dielectric layer adjacent to the semiconductor device, and an upper portion, which has a tapered top end that extends into a back end of the line (BEOL) dielectric layer. Also disclosed herein are embodiments of a method of forming the semiconductor structure. In the method, a cavity (also referred to herein as an air-gap) can be formed such that it has a lower section, which extends from a top surface of a MOL dielectric layer downward toward a semiconductor device, and an upper section, which extends from the top surface of the MOL dielectric layer upward and which is capped by an area of a BEOL dielectric layer having a concave bottom surface. A metallic fill material can be deposited into the cavity (e.g., through via openings) to form the metallic heating element. Such a metallic heating element can be employed to locally raise the temperature of the semiconductor device without exhibiting the same reliability issues associated with polysilicon-based heating elements. Also disclosed herein are embodiments of a method of employing such a metallic heating element to locally raise the temperature of a semiconductor device (e.g., during programming of an e-fuse or thermally tuning of some other type semiconductor device).

More particularly, disclosed herein are embodiments of a semiconductor structure. The semiconductor structure can include a semiconductor device. The semiconductor device could be, for example, an electronic fuse (e-fuse), a photonic or optical device (e.g., a ring resonator), or some other type of semiconductor device that might benefit from thermal tuning. The semiconductor device can further include dielectric layer (e.g., a middle of the line (MOL) blanket dielectric layer) over the semiconductor device. The semiconductor structure can further include a metallic heating element (e.g., tungsten heating element or some other suitable metal or metal alloy heating element). The metallic heating element can include a first portion (also referred to herein as a lower portion), which is within the dielectric layer adjacent to the semiconductor device, and a second portion (also referred to herein as an upper portion), which extends upward from the first portion above the level of the top surface of the dielectric layer and which has a tapered top end.

Also disclosed herein are embodiments of a method for forming a semiconductor structure. The method can include forming a semiconductor device. The semiconductor device could be, for example, an electronic fuse (e-fuse), a photonic or optical device (e.g., a ring resonator), or some other type of semiconductor device that might benefit from thermal tuning. The method can further include forming a dielectric layer (e.g., a middle of the line (MOL) blanket dielectric layer) over the semiconductor device. The method can further include forming a metallic heating element (e.g., a tungsten heating element or some other suitable metal or metal alloy heating element). The metallic heating element can specifically be formed such that it includes a first portion (also referred to herein as a lower portion), which is within the dielectric layer adjacent to the semiconductor device, and a second portion (also referred to herein as an upper portion), which extends upward from the first portion above the level of the top surface of the dielectric layer and which has a tapered top end.

Also disclosed herein are embodiments of a method of employing such a metallic heating element to locally raise the temperature of a semiconductor device (e.g., during programming of an e-fuse or thermally tuning of some other type semiconductor device). For example, the method can include accessing a semiconductor structure, as described above, where the semiconductor device is an electronic fuse (e-fuse). In this method, the metallic heating element can be used to facilitate programming of the e-fuse. Specifically, the method can include causing electric current to pass through the metallic heating element, thereby generating heat energy sufficient to raise the temperature of the e-fuse. The method can further include, when the temperature of the e-fuse has been raised, causing electric current to pass through the e-fuse in order to achieve programming.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1A is a layout diagram and FIGS. 1B and 1C are different cross-section diagrams illustrating an embodiment of a disclosed semiconductor structure;

FIG. 2A is a layout diagram and FIGS. 2B and 2C are different cross-section diagrams illustrating another embodiment of a disclosed semiconductor structure;

FIG. 3A is a layout diagram and FIGS. 3B and 3C are different cross-section diagrams illustrating yet another of a disclosed semiconductor structure;

FIG. 4A is a layout diagram and FIG. 4B is cross-section diagram illustrating yet another embodiment of a disclosed semiconductor structure;

FIG. 5A is a layout diagram and FIGS. 5B and 5C are different cross-section diagrams illustrating yet another of a disclosed semiconductor structure;

FIGS. 6-8 are cross-section diagrams illustrating alternatively heating elements that could be incorporated into the semiconductor structure embodiments of FIGS. 1A-5C;

FIG. 9 is a flow diagram illustrating disclosed method embodiments for forming the disclosed semiconductor structure embodiments;

FIG. 10A is a layout diagram and FIGS. 10B-10D are different cross-section diagrams illustrating a partially completed semiconductor structure formed according to the flow diagram of FIG. 9;

FIG. 11A is a layout diagram and FIGS. 11B-11D are different cross-section diagrams illustrating a partially completed semiconductor structure formed according to the flow diagram of FIG. 9;

FIGS. 12.1-12.6 are cross-section diagrams illustrating alternative trenches that could be etched at process 910 in the flow diagram of FIG. 9;

FIG. 13A is a layout diagram and FIGS. 13B-13D are different cross-section diagrams illustrating a partially completed semiconductor structure formed according to the flow diagram of FIG. 9;

FIG. 14A is a layout diagram and FIGS. 14B-14D are different cross-section diagrams illustrating a partially completed semiconductor structure formed according to the flow diagram of FIG. 9; and

FIG. 15 is a flow diagram illustrating an embodiment of a method for using a heating element, such as that in the semiconductor structure of FIGS. 1A-1C, 2A-2C, 3A-3C or 4A-4B, during programming of an electronic fuse.

### DETAILED DESCRIPTION

As mentioned above, chip designs may include one or more back end of the line (BEOL) heaters for heating one or more front end of the line (FEOL) semiconductor devices. However, given the separation distance between the BEOL and FEOL levels on a chip, meeting the thermal requirements of the semiconductor device(s) can be difficult. Middle of the line (MOL) polysilicon heaters have been developed that can be placed closer to the FEOL semiconductor devices, but these polysilicon heaters tend to exhibit reliability issues.

In view of the foregoing, disclosed herein are embodiments of a semiconductor structure including a semiconductor device (e.g., an electronic fuse (e-fuse) or some other type of device that can benefit from thermal tuning) and a metallic heating element adjacent thereto. The metallic heating element can have a lower portion, which is within a middle of the line (MOL) dielectric layer adjacent to the semiconductor device, and an upper portion, which has a tapered top end that extends into a back end of the line (BEOL) dielectric layer. Also disclosed herein are embodiments of a method of forming the semiconductor structure. In the method, a cavity (also referred to herein as an air-gap) can be formed such that it has a lower section, which extends from a top surface of a MOL dielectric layer downward toward a semiconductor device, and an upper section, which extends from the top surface of the MOL dielectric layer upward and which is capped by an area of a BEOL dielectric layer having a concave bottom surface. A metallic fill material can be deposited into the cavity (e.g., through via openings) to form the metallic heating element. Such a metallic heating element can be employed to locally raise the temperature of the semiconductor device without exhibiting the same reliability issues associated with polysilicon-based heating elements. Also disclosed herein are embodiments of a method of employing such a metallic heating element to locally raise the temperature of a semiconductor device (e.g., during programming of an e-fuse or thermally tuning of some other type semiconductor device).

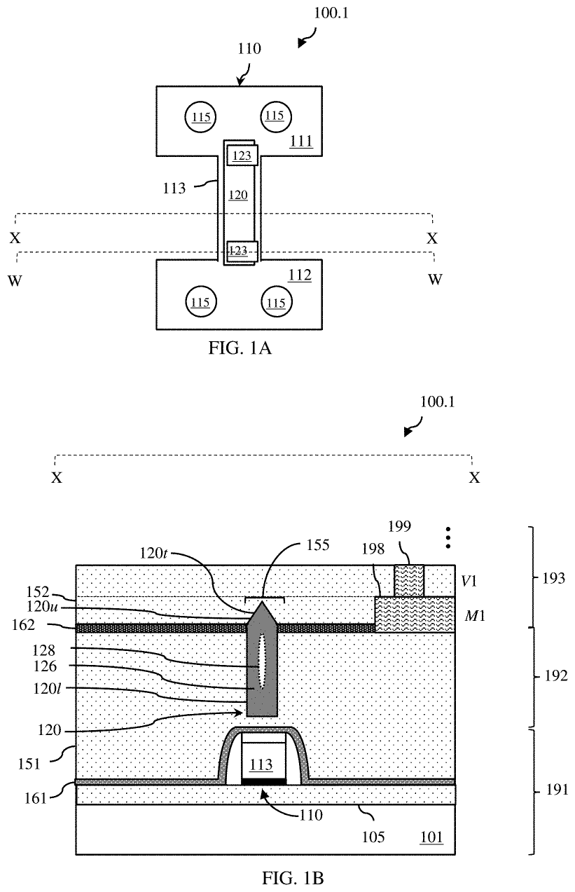

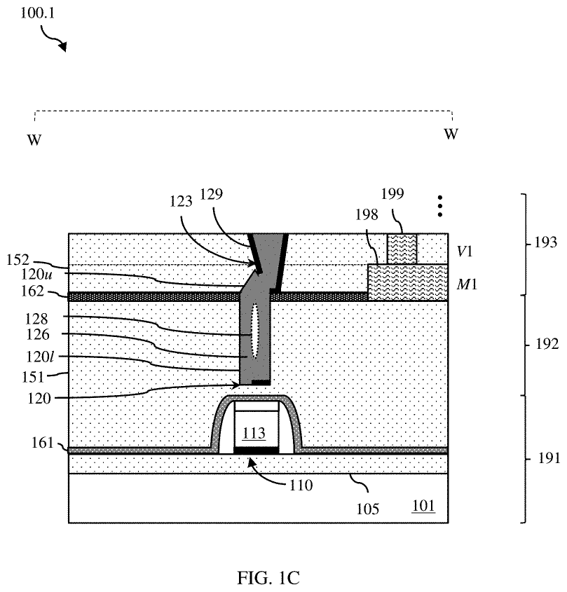

More particularly, FIGS. 1A-1C, 2A-2C, 3A-3C, 4A-4B, and 5A-5C disclosed herein are embodiments of a semiconductor structure 100.1, 100.2, 100.3, 100.4 and 100.5, respectively. The semiconductor structure 100.1, 100.2, 100.3, 100.4 and 100.5 can be a bulk semiconductor structure, a semiconductor-on-insulator structure, or a hybrid structure (which includes both bulk and semiconductor-on-insulator regions).

The semiconductor structure 100.1, 100.2, 100.3, 100.4 and 100.5 can include a front end of the line (FEOL) region 191. The FEOL region 191 can include a substrate 101. The substrate 101 can be, for example, a semiconductor substrate (e.g., a silicon substrate) or some other suitable type of substrate. The FEOL region 191 can further include one or more devices, which have been formed above the substrate 101 during FEOL processing. The semiconductor structure 100.1, 100.2, 100.3, 100.4 and 100.5 can further include a back end of the line (BEOL) region 193 above the devices. The BEOL region 193 can include the various metal and via levels (e.g., M1-V1, M2-V2, and so on) used to facilitate on-chip device-to-device connections on-chip and/or off-chip connections. The semiconductor structure 100.1, 100.2, 100.3, 100.4 and 100.5 can further include a middle of the line (MOL) region 192 between the FEOL region 191 and the BEOL region 193. The MOL region 192 can include contacts that extend through a MOL dielectric layer 152 between the devices in the FEOL region 191 and the metal and via levels in the BEOL region 193.

In the semiconductor structure 100.1, 100.2, 100.3, 100.4 and 100.5 at least one device in the FEOL region 191 can be a semiconductor device 110 of a type that could benefit from thermal coupling with heating element.

For example, in some embodiments, the semiconductor device 110 can be an e-fuse (e.g., as illustrated in the semiconductor structure 100.1, 100.2, 100.3, and 100.4 of FIGS. 1A-1C, 2A-2C, 3A-3C, and 4A-4B, respectively). Those skilled in the art will recognize that an e-fuse refers to a device that includes an anode 111, a cathode 112 and a relatively narrow fuse link 113 extending between the anode 111 and the cathode 112 (e.g., in an I-shape or some other similar shape). Contacts 115 landing on the anode 111 and cathode 112 can be employed to connect the anode 111 to a positive voltage source and the cathode 112 to a negative voltage source and, thereby cause current to flow across the fuse link 113 from the anode 111 to the cathode 112. For a polysilicon-based e-fuse, the components 111-113 can include polysilicon or, alternatively, salicided polysilicon. Such a polysilicon-based e-fuse can be concurrently formed during processing with gate first polysilicon or salicided polysilicon gate structures such that the polysilicon-based e-fuse include the same layers as the gate structures (e.g., a dielectric layer, a polysilicon layer on the dielectric layer and, optionally, a metal silicide layer on the polysilicon layer) and further such that the polysilicon-based e-fuse also includes sidewall spacers positioned laterally adjacent thereto. As illustrated in FIGS. 1A-1C, 2A-2C, 3A-3C, and 4A-4B, a polysilicon-based e-fuse can be formed above a shallow trench isolation (STI) region 105, which provides electrical isolation from semiconductor material below. In any case, if/when a sufficient amount of electric current is caused to flow through a polysilicon or salicide polysilicon fuse link 113 of a polysilicon-based e-fuse, the structure of the fuse link 113 can change thereby increasing the resistance of the fuse link 113 from a first resistance level to a second resistance level that is greater than the first resistance level. For example, in the case of a salicide polysilicon fuse link, current can cause silicide migration resulting in an increase in resistance. In other polysilicon-based e-fuses, current can cause melting, agglomeration, etc. such that resistance is increased. This process is known in the art as programming or blowing the e-fuse. Since the output voltage will increase with increased resistance, such a polysilicon-based e-fuse can be employed as a one-time programmable (OTP) memory that is either unprogrammed (i.e., has a low voltage level, also referred to as a low logic value) or programmed (i.e., has a high voltage level, also referred to as a high logic value). As discussed above, typically, with such polysilicon-based e-fuses, the amount of electric current required to achieve programming can be quite high and generation of the high electric current requires a large amount of area-consuming support circuitry and current drivers. In the disclosed semiconductor structure, a unique heating element 120 (discussed in greater detail below) that doesn't suffer from the same disadvantages as prior art heating elements can be employed to locally heat the e-fuse prior to program, thereby reducing the amount of electric current needed to program the e-fuse and in turn reducing area-consumption.

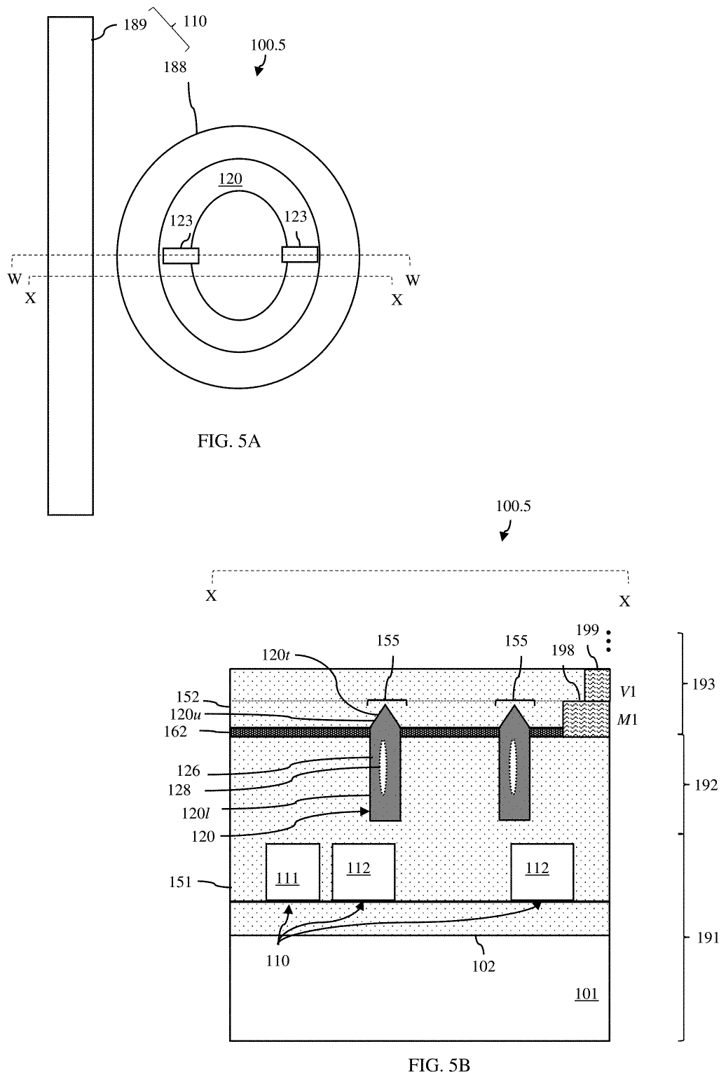

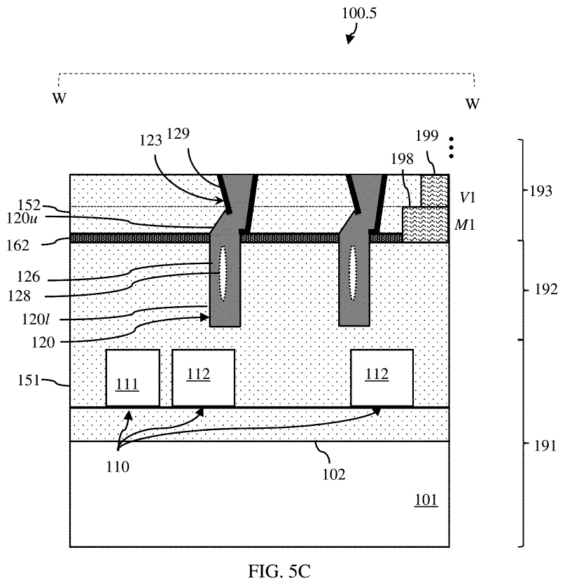

In other embodiments, the semiconductor device 110 could be, for example, a photonic or optical device (e.g., as illustrated in the semiconductor structure 100.5 of FIGS. 5A-5C). For example, the photonic or optical device could be a ring resonator. A ring resonator can include bus waveguide 189 positioned laterally adjacent and optically coupled to a closed-curve waveguide 1188 (also referred to herein as a ring waveguide). In such a ring resonator, light signals can enter the bus waveguide 189 at an input end and pass out an output end. Due to optical coupling and particularly the creation of an evanescent field between the adjacent waveguides 188-189, some light signals can pass from the bus waveguide 189 into the closed-curve waveguide 188 and some light signals can pass from the closed-curve waveguide 188 into the bus waveguide 189. However, within the closed-curve waveguide 188, only light signals of a specific resonant wavelength for that closed-curve waveguide will make repeated roundtrips through the closed-curve waveguide, building up intensity, due to constructive interference. As a result, the light signals that pass from the closed-curve waveguide 188 into the bus waveguide 189 and out at the output end of the bus waveguide 189 will, predominantly, have the specific resonant wavelength. The waveguides 188-189 of a ring resonator could, for example, be semiconductor waveguides (e.g., silicon waveguides) above an insulator layer 102 (e.g., a buried oxide layer) in a semiconductor-on-insulator (e.g., a silicon-on-insulator structure). In any case, closed-curve waveguides are known to be thermally sensitive (i.e., they exhibit temperature-dependent resonance shifts (TDRS)). In the disclosed semiconductor structure, a unique heating element 120 (discussed in greater detail below) that doesn't suffer from the same disadvantages as prior art heating elements can be employed to thermally tune the closed-curve waveguide 188 and, thereby minimize temperature-dependent resonance shifts (TDRS) (i.e., avoid temperature-dependent variations in the resonant wavelength of the closed-curve waveguide 188).

In other embodiments (not shown), the FEOL semiconductor device 110 could be any other type of device that could benefit from thermal coupling with the unique heating element 120.

As mentioned above currently available BEOL heaters may be too far removed from FEOL devices to provide the desired local temperature increase and currently available MOL polysilicon heaters tend to exhibit reliability issues. The semiconductor structure 100.1, 100.2, 100.3, 100.4 and 100.5 disclosed herein can include a unique heating element 120. This heating element 120 can be contacted by at least two vias 123 so that a voltage differential on the vias 123 can cause electric current to pass through the heating element 120, thereby generating thermal energy. Those skilled in the art will recognize that the direction and amount of current flow will depend upon the voltage differential. Furthermore, the amount of heat generated per unit length will depend upon the material used and the current density (which is a function of the cross-sectional area of the heating element). In any case, this heating element 120 can be configured so that it doesn't suffer from the disadvantages mentioned above. For example, this heating element 120 can be at least partially contained within the MOL region 192 so that it is close enough to the semiconductor device 110 to locally raise the temperature of the semiconductor device 110 by some desired amount. Furthermore, the heating element 120 can be a metallic heating element and, particularly, a metal or metal alloy heating element and specifically not a polysilicon-based heating element subject to reliability issues.

More particularly, the semiconductor structure 100.1, 100.2, 100.3, 100.4 and 100.5 can optionally include one or more thin conformal dielectric layers covering the devices in the FEOL region 191 (including the semiconductor device 110). For example, a relatively thin etch stop layer 161 (e.g., a relatively thin silicon nitride layer or one or more layers of some other suitable etch stop material) can cover the semiconductor devices. The semiconductor structure 100.1, 100.2, 100.3, 100.4 and 100.5 can further include, in the MOL region 192, a dielectric layer 151 and, more particularly, a middle of the line (MOL) blanket dielectric layer on the etch stop layer 161, if applicable. This dielectric layer 151 can be a layer of interlayer dielectric (ILD) material. The ILD material can include, for example, borophosphosilicate glass (BPSG). Alternatively, the ILD material can include some other doped silicon glass (e.g., phosphosilicate glass (PSG)), silicon dioxide or other suitable ILD material. In any case, the dielectric layer 151 can have an essentially planar top surface.

The semiconductor structure 100.1, 100.2, 100.3, 100.4 and 100.5 can optionally include one or more thin conformal dielectric layers covering the top surface of the dielectric layer 151. For example, an additional relatively thin etch stop layer 162 (e.g., a relatively thin silicon nitride layer or one or more layers of some other suitable etch stop material) can cover the top surface of the dielectric layer 151.

The semiconductor structure 100.1, 100.2, 100.3, 100.4 and 100.5 can further include, in the BEOL region 193, additional dielectric layers for the various BEOL metal and via levels (e.g., M1-V1, M2-V2, and so on). These additional dielectric layers can include, for example, a stack of relatively thick dielectric layers (e.g., thick ILD material layers) for each metal level and each vial level (e.g., in the case single damascene processing) or for each combined metal and via level (e.g., in the case of dual damascene processing). The additional dielectric layers can also include relatively thin dielectric layers (e.g., etch stop layers) therebetween.

The metallic heating element 120 can be a metal or metal alloy filled-cavity and the vias 123 can similarly be metal or metal alloy filled-via openings. Specifically, the semiconductor structure 100.1, 100.2, 100.3, 100.4 and 100.5 can include a cavity. This cavity can have a first section (also referred to herein as a lower section) in the MOL region 192 within the dielectric layer 151 and, particularly, extending from the top surface of the dielectric layer 151 downward (e.g., as a trench) such that it has a bottom or side surface adjacent to (without contacting) the semiconductor device 110. The cavity can further have a second section (also referred to herein as an upper section), which extends upward from the first section (i.e., away from the top surface of the dielectric layer 151) and into the BEOL region 193. The cavity and, more particularly, the second section of the cavity can be capped by an additional dielectric layer 152 in the BEOL region 193. It should be noted that a concave area 155 in the bottom surface of this additional dielectric layer 152 forms the capped end wall of the cavity. In some embodiments, this concave area 155 in the bottom surface of the additional dielectric layer 152 can form a V-shape or a deep-V shape. The additional dielectric layer 152 can be the same ILD material as that used for the dielectric layer 151. Alternatively, the additional dielectric layer 152 can be a different ILD material than that used for the dielectric layer 151. For example, in some embodiments, the dielectric layer 151 could, as mentioned above, be a BPSG layer and the additional dielectric layer 152 could be a layer of silicon dioxide or some other oxide.

The semiconductor structure 100.1, 100.2, 100.3, 100.4 and 100.5 can further include at least two via openings that extend into the additional dielectric layer 152 to different portions of the cavity (e.g., to opposite ends of the cavity).

The via openings can be lined with a metallic liner 129. The metallic liner 129 can include one or more layers of metallic liner material including, for example, an adhesion material and a diffusion barrier material. In some embodiments, the layer of adhesion material could be, for example, a layer of titanium or tantalum and the layer of diffusion barrier material could be, for example, a layer of titanium nitride or tantalum nitride. Alternatively, any other metallic liner material(s) could be used for the metallic liner 129. It should be noted that, due to the deposition technique used to form the metallic liner 129 in the via openings during processing, metallic liner material can also be contained within the cavity (e.g., aligned below the via openings, as illustrated).

The cavity and the via openings can also be filled with a metallic fill material 126. It should be noted that, due to the deposition technique used to fill the cavity and via openings with the metallic fill material 126, one or more voids 128 (i.e., air or gas-filled bubble(s)) may be trapped within the metallic fill material 126, as illustrated. In some embodiments, the metallic fill material 126 could be a tungsten or tungsten alloy fill material. Alternatively, the metallic fill material 126 could be any other suitable metal or metal alloy fill material, which could be deposited through via openings into the cavity during processing and which exhibits suitable conductive-resistive properties such that, when a voltage differential at the vias 123 causes electric current to flow through the heating element 120, heat energy is generated (e.g., molybdenum or alloys thereof, nickel or alloys thereof, etc.). It should be noted that the metallic fill material 126 contained in the cavity and via openings can be either the same metal or metal alloy material or a different metal or metal alloy material used for adjacent metal wires or vias 198-199 at the same level in the BEOL region 193. For example, in some embodiments, the metallic fill material 126 can be a tungsten or tungsten alloy fill material and the adjacent metal wires and vias 198-199 could be the same tungsten or tungsten alloy material. In other embodiments, the metallic fill material 126 can be a tungsten or tungsten alloy fill material and the adjacent metal wires and vias 198-199 could be copper, aluminum, or any other different metal or metal alloy material suitable for use in BEOL metal wires or vias.

In any case, the metallic heating element 120 (including the metallic fill material 126 and any metallic liner material within the cavity) can include a first portion 120/(also referred to herein as a lower portion) and a second portion 120u (also referred to as an upper portion) above the first portion 1201. The first portion 1201 can be seated in the first section of the cavity and, thus, in the MOL region 192 within the dielectric layer 151 and adjacent to the semiconductor device 110. The second portion 120u (also referred to herein as an upper portion) can be seated within the second section of the cavity and, thus, in the BEOL region 193 extending upward from the top surface of the dielectric layer 152. Since the second portion 120u of the metallic heating element 120 is seated within the second section of the cavity, the shape of the concave area 155 in the bottom surface of the additional dielectric layer 152 (i.e., the shape of the capped end wall of the cavity) defines the shape of the top end 120t of the second portion 120u of the metallic heating element 120. Thus, the top end 120t is tapered (i.e., a tapered top end) with, for example, a V-shape or deep V-shape, as illustrated.

As mentioned above, the first section of the cavity, which contains the first portion 1201 of the metallic heating element 120, will have a bottom or side surface adjacent to (without contacting) the semiconductor device 110. It should be sufficiently close to the semiconductor device 110 to achieve thermal coupling therewith. In other words, the heating element 120 and, particularly, the first portion 1201 thereof should be placed such that heat energy generated by the heating element 120 will pass through the ILD material of the dielectric layer 151 to the semiconductor device 110, thereby locally raising the temperature of the semiconductor device 110. The heating element 120 and, particularly, the first portion 1201 thereof should further be placed such that it remains physically separated from semiconductor device 110 to prevent shorting.

Placement of the heating element 120, the overall shape of the heating element 120, as well as overall size of the heating element (including the sizes of the first and second portions thereof) can vary depending upon a number of different design factors. These factors can include, but are not limited to, the type, shape, size and number of semiconductor device(s) to be heated.

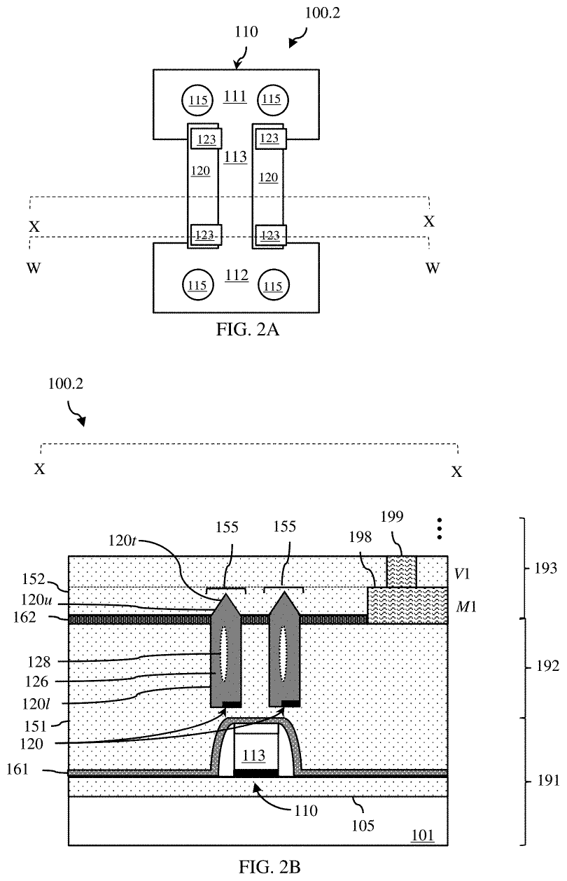

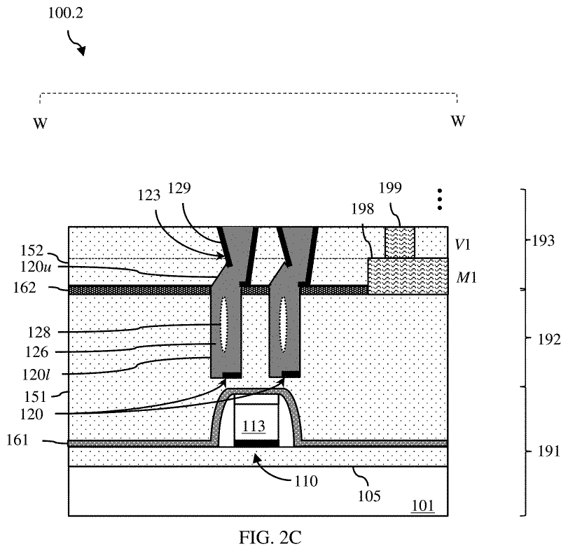

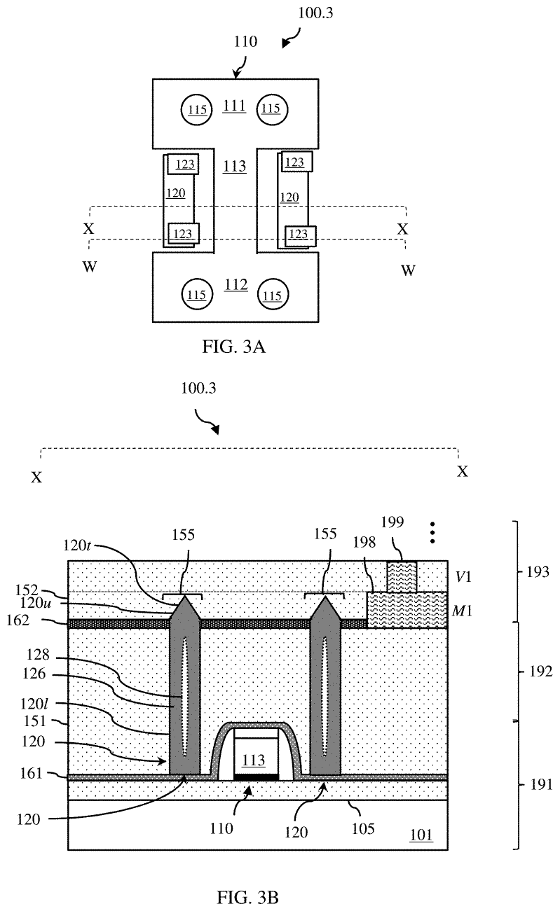

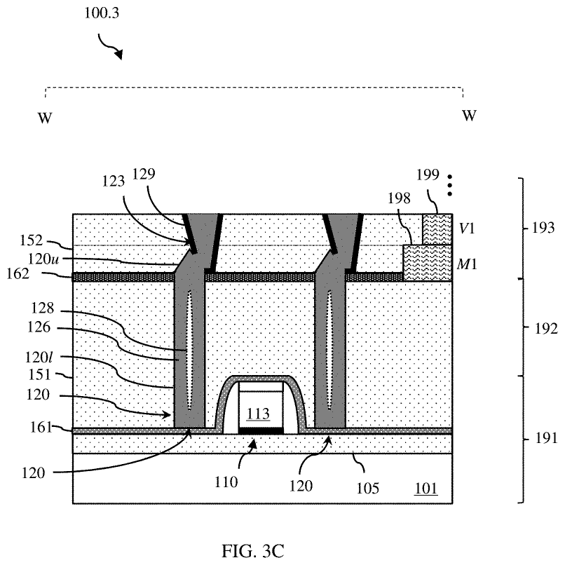

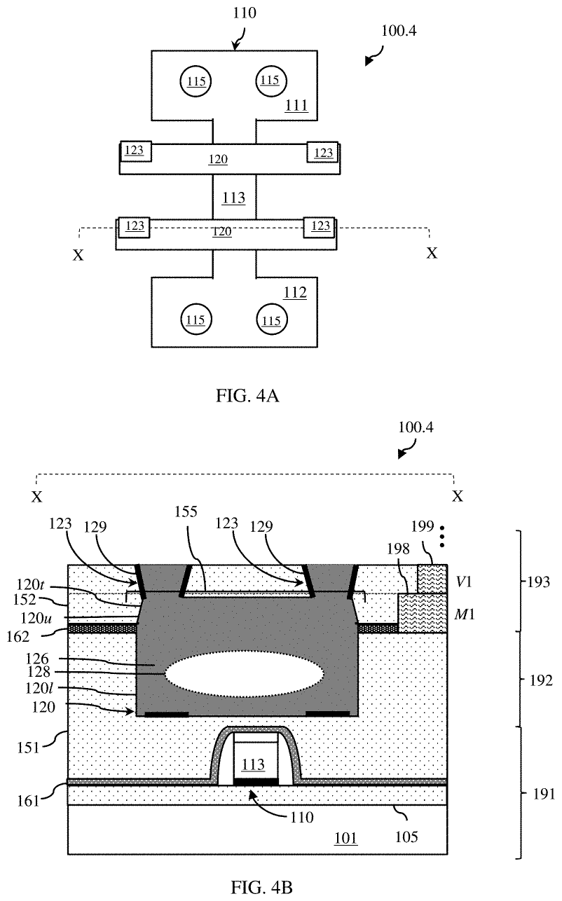

For example, as mentioned above, in the semiconductor structure 100.1, 100.2, 100.3, and 100.4 of FIGS. 1A-1C, 2A-2C, 3A-3C, and 4A-4B, the semiconductor device 110 could be, for example, a polysilicon-based e-fuse. Typically, the fuse link 113 of such an e-fuse has an elongated relatively thin rectangular shape (i.e., a linear shape). In this case, the first portion 1201 of each heating element adjacent to a fuse link 113 can, for example, also have an elongated relatively thin rectangular shape (i.e., a linear shape) that is essentially parallel to or perpendicular to the fuse link. For example, as illustrated in the semiconductor structure 100.1 of FIGS. 1A-1C, the heating element 120 and, particularly, the first portion 1201 thereof can be aligned above and parallel to the fuse link 113 of the e-fuse. Alternatively, as illustrated in the semiconductor structure 100.2 of FIGS. 2A-2C, the heating element 120 and, particularly, the first portion 1201 thereof could be above, parallel to and overlapping a side of the fuse link 113 of the e-fuse. Optionally, a pair of heating elements 120 could be above, parallel to, and overlapping opposing sides of the fuse link 113 of the e-fuse (e.g., also as illustrated in the semiconductor structure 100.2 of FIGS. 2A-2C). Alternatively, as illustrated in the semiconductor structure 100.3 of FIGS. 3A-3C, the heating element 120 and, particularly, the first portion 1201 thereof could be positioned laterally adjacent and parallel to the fuse link 113 of the e-fuse such that it is completely offset from the fuse link 113 (i.e., not directly above the fuse link 113). For purposes of illustration, the first portion 1201 is shown in FIGS. 3B-3C as extending vertically from the bottom surface of the dielectric layer 151 to the top surface of the dielectric layer 151. However, alternatively, the first portion 1201 could extend only partially through the dielectric layer 151. That is, the bottom of the first portion 1201 could be some distance above the level of the bottom surface of the dielectric layer 151 and either below the level of the top of the fuse link 113 or even above the level of the top of the fuse link. Optionally, a pair of heating elements 120 could be positioned laterally adjacent to opposing sides of the fuse link 113 of the e-fuse and can extend to the bottom surface of the dielectric layer 151 (e.g., also as illustrated in the semiconductor structure 100.3 of FIGS. 3A-3C). Alternatively, as illustrated in the semiconductor structure 100.4 of FIGS. 4A-4B, the heating element 120 and, particularly, the first portion 1201 thereof could be above and perpendicular to the fuse link 113 of the e-fuse. Optionally, multiple heating elements 120 could be above and perpendicular to the fuse link 113 of the e-fuse (e.g., also as illustrated in the semiconductor structure 100.4 of FIGS. 4A-4B). It should be noted that one advantage of the embodiment shown in FIGS. 4A-4B is that multiple heating elements could be perpendicular to and traverse multiple fuse links of multiple adjacent e-fuses (i.e., multiple heating elements could be shared by multiple e-fuses).

Also, as mentioned above, in the semiconductor structure 100.5 of FIGS. 5A-5C, the semiconductor device 110 could be a photonic or optical device (e.g., a ring resonator). In this case, the heating element 120 can be adjacent to a closed-curved waveguide 188 of the ring resonator and can have a similar curved shape. The first portion 1201 of the heating element 120 can be aligned above the inside edge of the closed-curve waveguide, as illustrated. Alternatively, the first portion 1201 of the heating element 120 could be offset from the inside edge (e.g., in area defined by the inside edge of the curve) and, optionally, can extend from the top surface of the dielectric layer 151 down to the bottom surface (not shown).

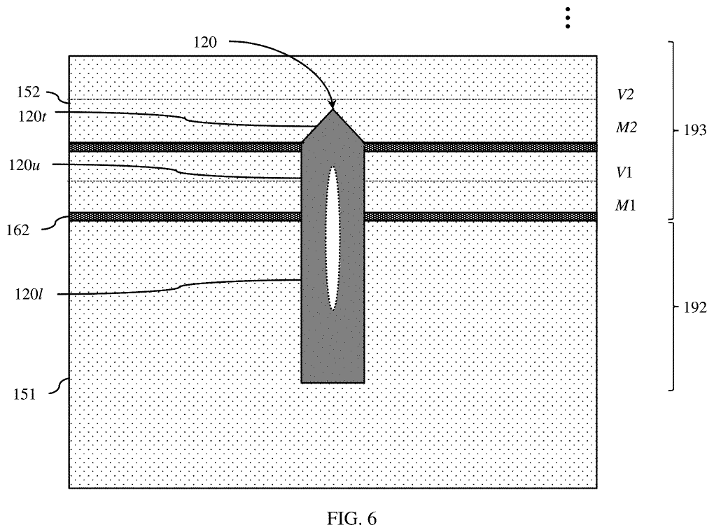

As illustrated in FIGS. 1A-5C, the additional dielectric layer 152 that caps the cavity, which as discussed above contains the metallic heating element 120, can be the lowest dielectric layer in the BEOL region 193. That is, the tapered top end 120t of the second portion 120u of the heating element may only extend into the lowest BEOL metal level (M1) (e.g., through the etch stop layer 162 and into the additional dielectric layer 152). Alternatively, as illustrated in FIG. 6, the additional dielectric layer 152 that caps the cavity can be some upper dielectric layer in the BEOL region 193. Thus, the second portion 120u of the heating element 120 may extend completely through one or more of the BEOL metal and via levels and the tapered top end 120t may extend into some higher BEOL metal or via level (e.g., into M2, as illustrated).

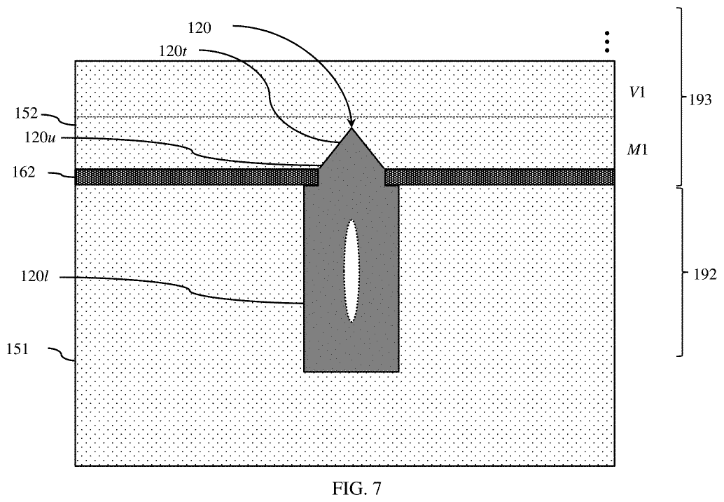

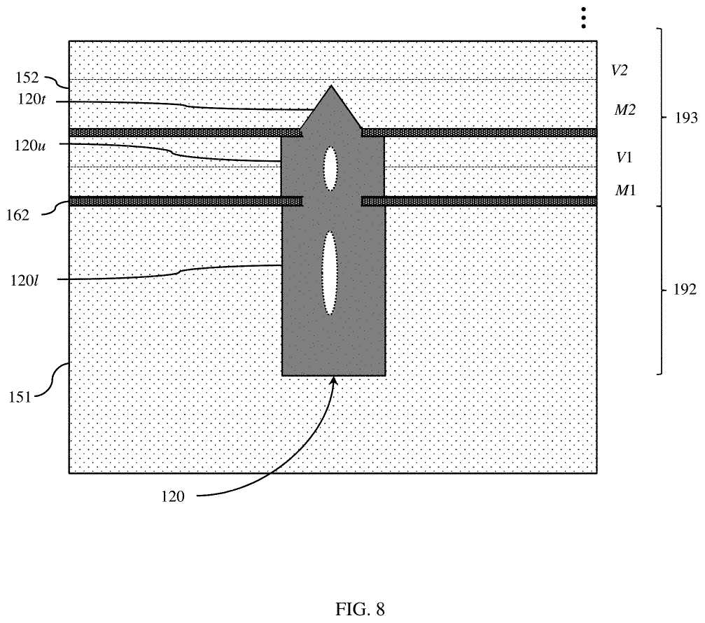

As illustrated in FIGS. 1A-5C, except for the tapered top end 120t, the width of the heating element 120 can be essentially uniform. Alternatively, as illustrated in FIGS. 7 and 8, any portion of the heating element 120 extending through an etch stop layer (e.g., see etch stop layer 161) can have a first width and at least the first portion 1201 of the heating element 120, which is within the dielectric layer 151, can have a second width that is greater than the first width.

It should be noted that the exemplary heating elements 120 described above and illustrated in FIGS. 1A-8 are provided for illustration purposes only and are not intended to be limiting. Alternatively, any other suitable heating element shape, size or metal material could be employed in which the heating element includes a metallic fill material, which fills a cavity as described above.

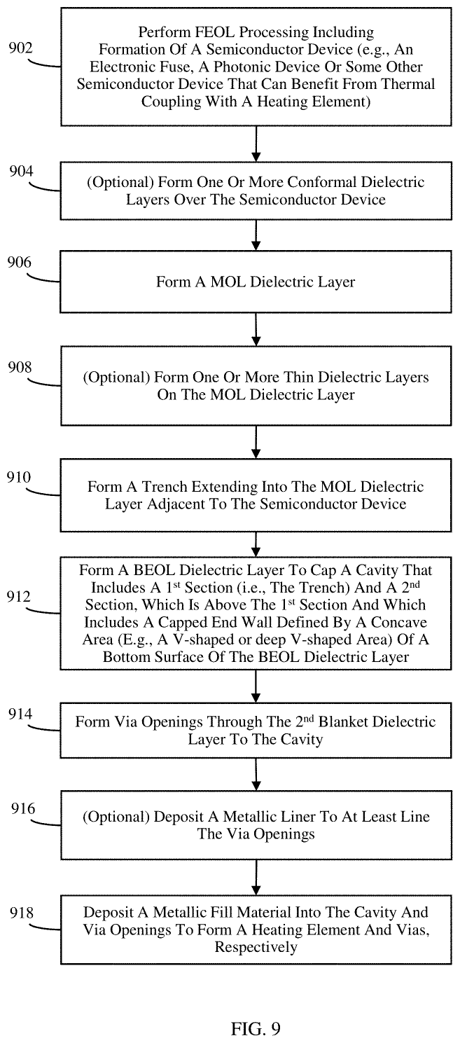

Referring to the flow diagram of FIG. 9, also disclosed herein are method embodiments for forming a semiconductor structure, such as any of the semiconductor structures 100.1, 100.2, 100.3, 100.4 and 100.5 described above and illustrated in FIGS. 1A-1C, 2A-2C, 3A-3C, 4A-4B, and 5A-5C, respectively.

The method can include accessing an initial semiconductor structure. The initial semiconductor structure can be, for example, a bulk semiconductor structure, a semiconductor-on-insulator structure, or a hybrid structure (which includes both bulk and semiconductor-on-insulator regions).

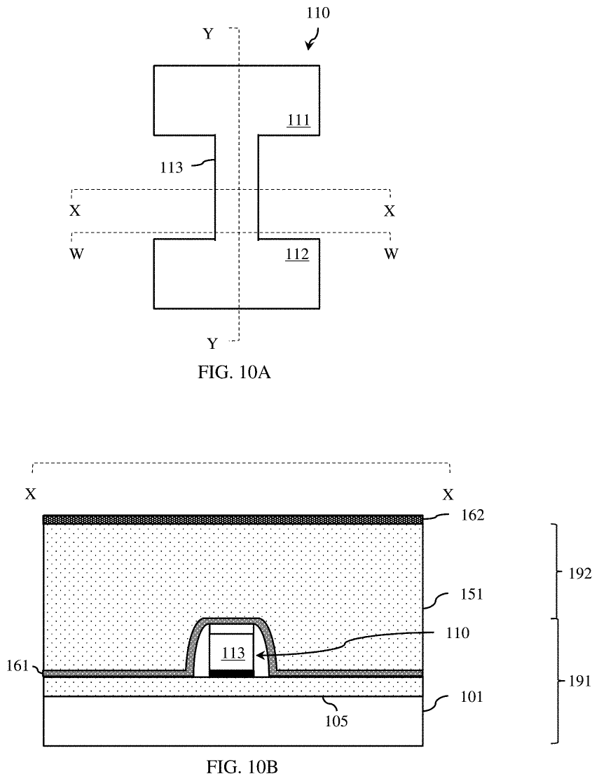

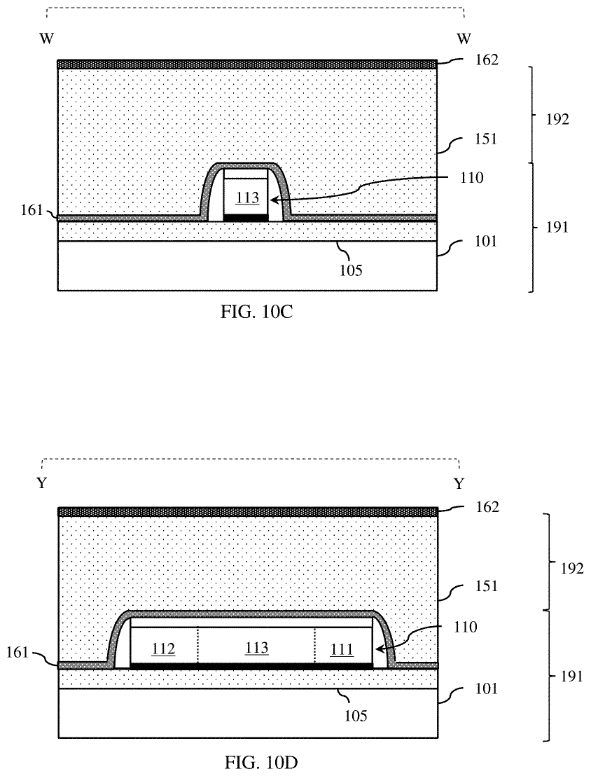

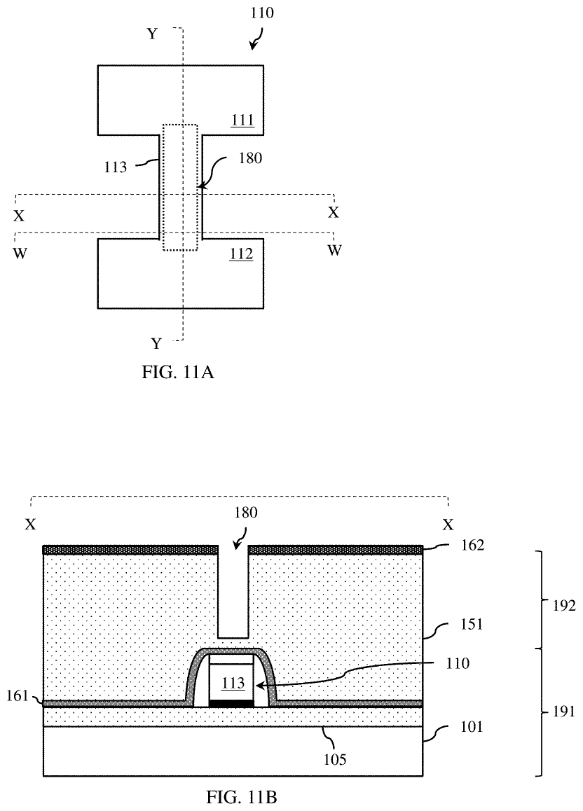

The method can further include performing front end of the line (FEOL) processing (see process 902 and FIGS. 10A-10D). FEOL processing can include formation of one or more devices including at least one semiconductor device 110, which could benefit from thermal coupling with heating element.

In some embodiments, the semiconductor device 110 formed at process 902 could be a polysilicon-based electronic fuse (e-fuse), as illustrated. As discussed in detail above with regard to the structure embodiments, an e-fuse refers to a device that includes an anode 111, a cathode 112 and a relatively narrow fuse link 113 extending between the anode 111 and the cathode 112 (e.g., in an I-shape or some other similar shape). Techniques for forming such e-fuses and, particularly, polysilicon are well known in the art and, thus, details thereof have been omitted from the specification in order to allow the reader to focus on the salient aspects of the disclosed embodiments.

It should be noted that, for purposes of illustrating the disclosed method, only a polysilicon-based e-fuse is shown in the drawings as being formed at process 902. However, the figures are not intended to be limiting. It should be understood that, alternatively, the semiconductor device 110 formed at process 902 could be a photonic or optical device (e.g., a ring resonator, as described in detail above with regard to the semiconductor structure 100.5 of FIGS. 5A-5C) or any other suitable semiconductor device that could benefit from thermal coupling with a heating element. Techniques for forming such devices are well known in the art and, thus, the details thereof have been omitted from the specification in order to allow the reader to focus on the salient aspects of the disclosed embodiments.

The method can further include forming one or more thin conformal dielectric layers covering the devices in the FEOL region 191 (including the semiconductor device 110) (see process 904 and FIGS. 10A-10D). For example, a relatively thin etch stop layer 161 (e.g., a relatively thin silicon nitride layer or one or more layers of some other suitable etch stop material) can be conformally deposited (e.g., by chemical vapor deposition (CVD), plasma-enhanced CVD (PECVD) or any other suitable deposition technique) so as to cover the semiconductor devices.

The method can further include forming a dielectric layer 151 and, more particularly, a middle of the line (MOL) blanket dielectric layer on the etch stop layer 161, if applicable, and over the semiconductor device(s) (see process 906 and FIGS. 10A-10D). This dielectric layer 151 can be a layer of interlayer dielectric (ILD) material. The ILD material can include, for example, borophosphosilicate glass (BPSG) deposited by CVD or some other suitable deposition technique. Alternatively, the ILD material can include some other doped silicon glass (e.g., phosphosilicate glass (PSG)), silicon dioxide or other suitable ILD material. In any case, the dielectric layer 151 can be subjected to a polishing processes (e.g., a chemical mechanical polishing (CMP) process) such that the top surface of the dielectric layer 151 is essentially planar.

The method can optionally include forming one or more thin conformal dielectric layers covering the top surface of the dielectric layer 151 (see process 908 and FIGS. 10A-10D). For example, an additional relatively thin etch stop layer 162 (e.g., a relatively thin silicon nitride layer or one or more layers of some other suitable etch stop material) can be deposited (e.g., by CVD or some other suitable deposition technique) so as to cover the top surface of the dielectric layer 151.

The method can further include forming a cavity that will define the shape of a metal heating element contained therein. Specifically, a first section 1801 (also referred to herein as a lower section) of a cavity 180 can be formed (e.g., lithographically patterned and etched) so that it extends through the etch stop layer 161 and further in the MOL region 192 from the top surface of the dielectric layer 151 downward (e.g., as a trench) and so that it has a bottom or side surface adjacent to (without contacting) the semiconductor device 110 (see process 910).

Formation of the first section 1801 of the cavity 180 (e.g., placement, size, shape, etc.) can vary depending upon a number of different design factors. These factors can include, but are not limited to, the type, shape, size and number of semiconductor device(s) to be heated.

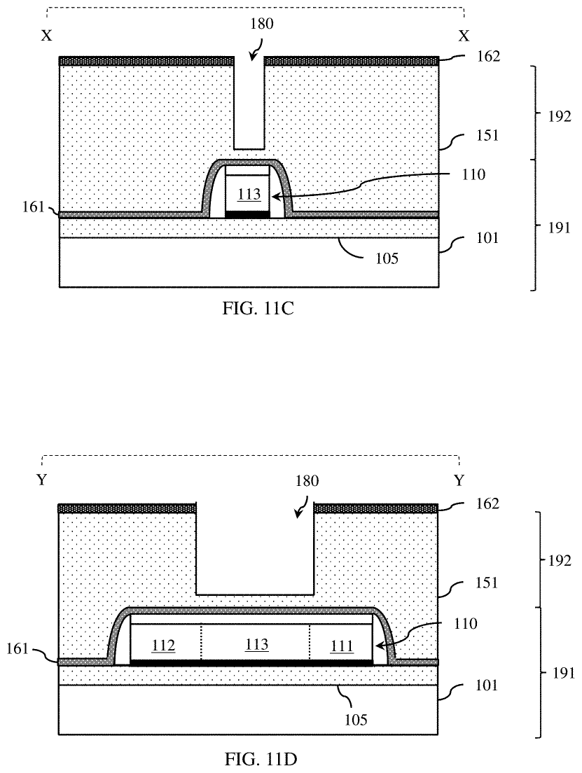

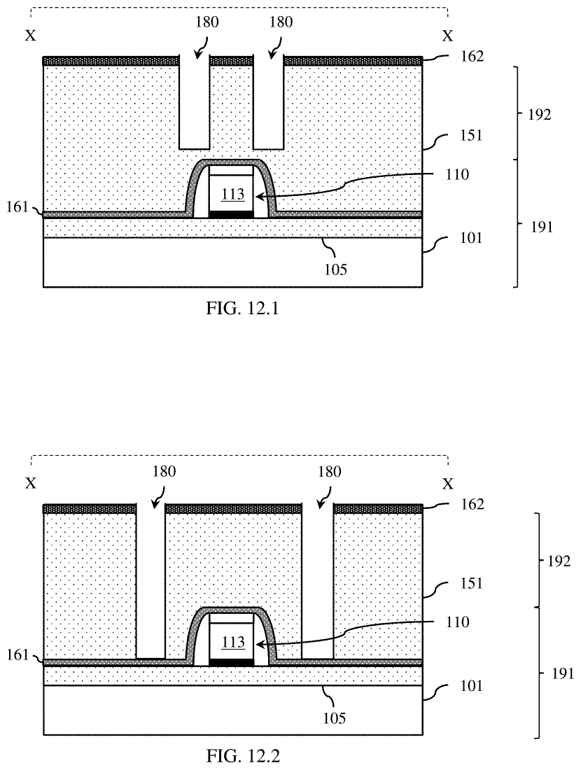

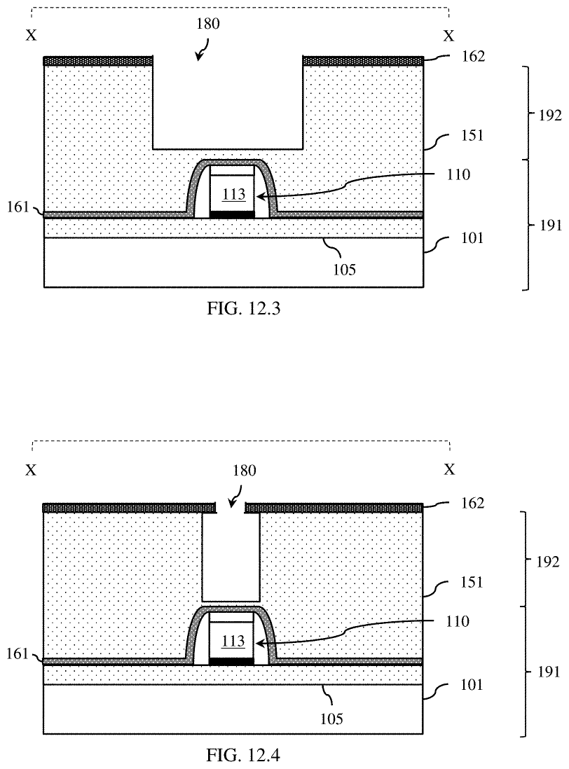

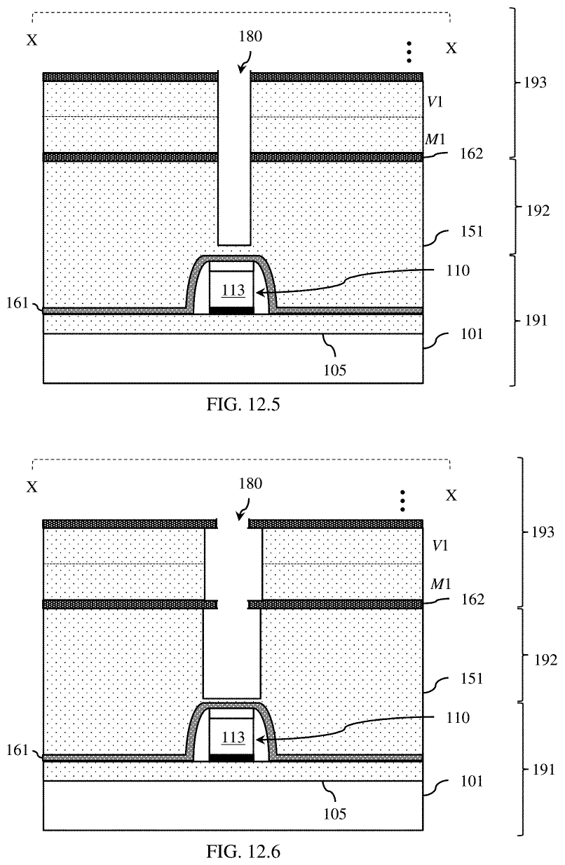

For example, as mentioned above, the semiconductor device 110 could be a polysilicon-based e-fuse. The fuse link 113 of such an e-fuse has an elongated relatively thin rectangular shape (i.e., a linear shape). In this case, the first section 1801 of the cavity 180 can be lithographically patterned and etched so that it is adjacent to a fuse link 113 and so that it also has an elongated relatively thin rectangular shape (i.e., a linear shape) that is essentially parallel to or perpendicular to the fuse link. For example, as illustrated in the partially completed structure shown in FIGS. 11A-11D, the first section 1801 of the cavity can be aligned above and parallel to the fuse link 113 of the e-fuse. Alternatively, as illustrated in the partially completed structure shown in FIG. 12.1, the first section 1801 could be above, parallel to, and can overlap one side of the fuse link 113 of the e-fuse. Optionally, a pair of first sections 1801 for a pair of cavities could be above, parallel to, and overlapping opposing sides of the fuse link 113 of the e-fuse (e.g., also as illustrated in the partially completed structure of FIG. 12.1). Alternatively, as illustrated in the partially completed structure of FIG. 12.2, the first section 1801 could be positioned laterally adjacent and parallel to the fuse link 113 of the e-fuse. For purposes of illustration, the first section 1801 is shown in FIG. 12.2 as extending vertically from the top surface of the dielectric layer 151 to the bottom surface of the dielectric layer 151. However, alternatively, the first section 1801 could extend only partially into the dielectric layer 151. That is, the first section 1801 could be etched so that the bottom is some distance above the level of the bottom surface of the dielectric layer 151 and either below the level of the top of the fuse link 113 or even above the level of the top of the fuse link. Optionally, this first section 1801 could extend from the top surface of the dielectric layer 151 to the bottom surface of the dielectric layer 151 (e.g., also as illustrated in the partially completed structure of FIG. 12.2). Optionally, a pair of heating elements 120 could be positioned laterally adjacent to opposing sides of the fuse link 113 of the e-fuse and can extend from the top surface of the dielectric layer 151 to the bottom surface of the dielectric layer 151 (e.g., also as illustrated in the partially completed structure of FIG. 12.2). Alternatively, as illustrated in the partially completed structure of FIG. 12.3, one or more first sections 1801 of one or more cavities could be above and perpendicular to the fuse link 113 of the e-fuse. Optionally, as illustrated in the partially completed structure of FIG. 12.4, following formation of the first section 1801 (i.e., following formation of the trench), additional processing and, particularly, a selective isotropic etch process could be performed in order to widen the first section 1801. Alternatively, as illustrated in the partially completed structures of FIGS. 12.5 and 12.6, formation and widening, if applicable, of the first section 1801 can be performed following some BEOL processing including formation of one or more metal/via levels in the BEOL region 193.

Alternatively, the first section 1801 of the cavity 180 can be lithographically patterned and etch so as to have any other suitable shape, size, placement, etc., within the dielectric layer 151. For example, if the semiconductor device 110 is a photonic or optical device, such as a ring resonator, then the first section 1801 of the cavity 180 could have a curved shape similar to that of a closed-curve waveguide in the ring resonator. Furthermore, the first section 1801 of the cavity 180 could be aligned above the inside edge of that closed-curve waveguide, offset from the inside edge (e.g., in area defined by the inside edge of the curve), etc.

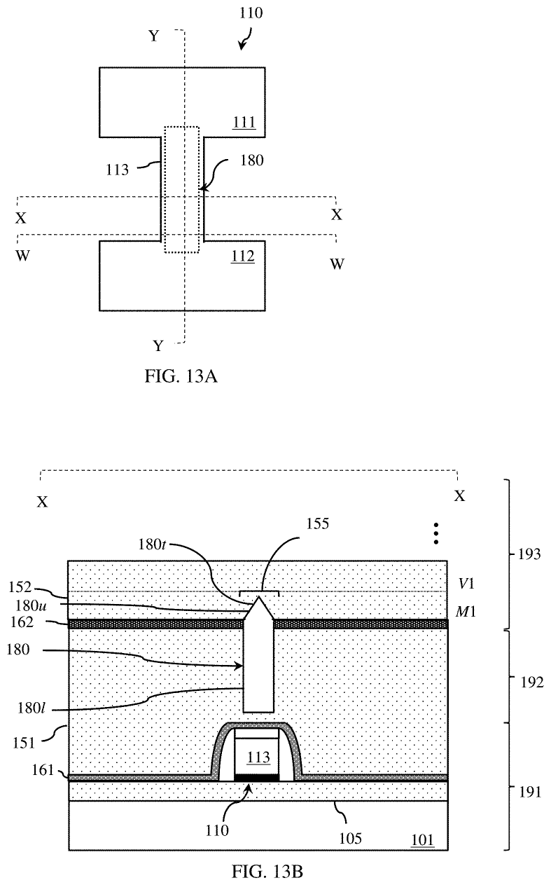

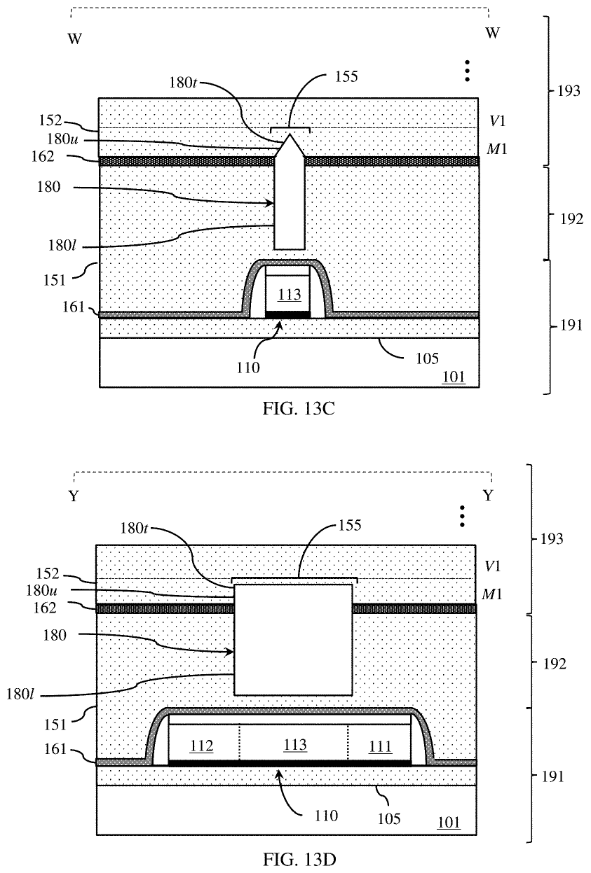

In any case, a second section 180u of the cavity 180 will extend above the level of the top surface of the MOL dielectric layer 151 and an additional dielectric layer 152 (i.e., a BEOL dielectric layer) can be deposited so as to cap (i.e., completely enclose) the cavity 180 (see process 912 and FIGS. 13A-13D). FIGS. 13A-13D show the additional dielectric layer 152 caping the cavity 180 from the partially completed structure shown in FIGS. 11A-11D. It noted that a concave area 155 in the bottom surface of this additional dielectric layer 152 forms the capped end of the cavity. It should be understood that essentially the same process step can be performed with respect to the cavities shown in FIGS. 12.1-12.6. Specifically, the additional dielectric layer 152 can be the same ILD material or a different ILD material than that used for the dielectric layer 151. For example, in some embodiments, the additional dielectric layer 152 can be a layer of silicon dioxide or some other oxide deposited by plasma-enhanced chemical vapor deposition (PECVD). Those skilled in the art will recognize that, during PECVD of an oxide, material typically deposits faster on the edges (corners) of a trench than it does on the adjacent planar surface. As a result, the bottom surface of the additional dielectric layer 152 being deposited will have a concave area (e.g., a V-shaped area or deep V-shaped area) aligned above the opening to the trench (i.e., this concave area 155 in the bottom surface of this additional dielectric layer 152 forms the capped end 180t of the cavity 180).

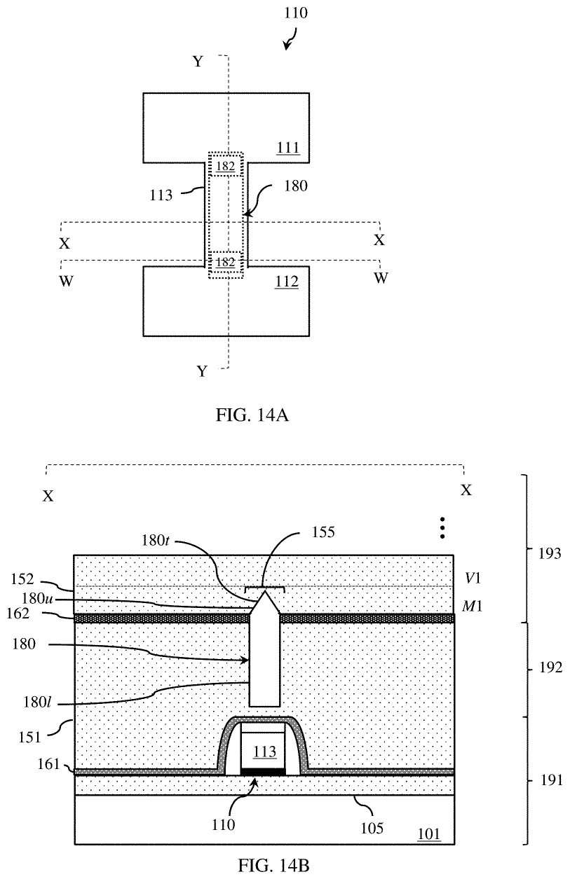

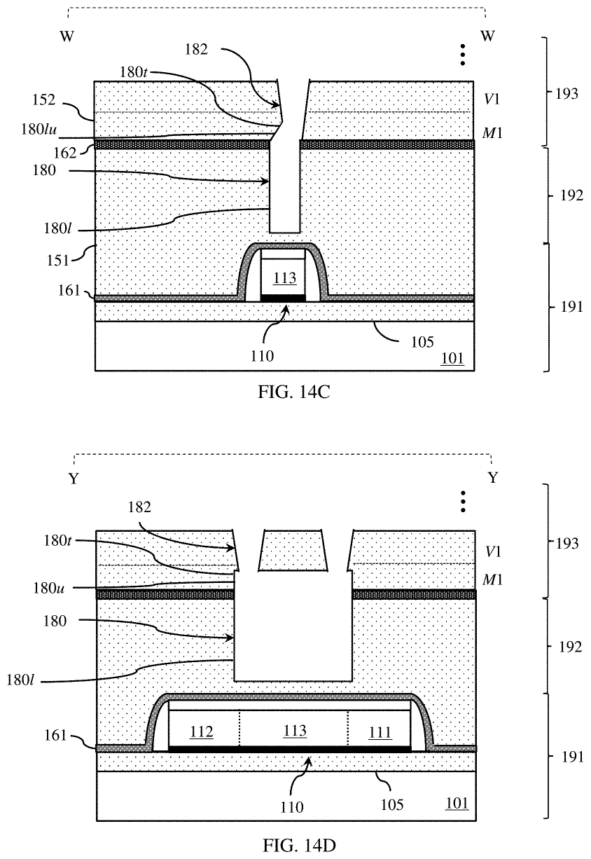

The method can further include forming at least two via openings 182 (see process 914 and FIGS. 14A-14D). The via openings 182 can be lithographically patterned and etched such that that extend into the additional dielectric layer 152 to different portions of the cavity 180 (e.g., to opposite ends of the cavity 180).

The method can further include lining the via openings 182 with a metallic liner 129 (see process 916 and FIGS. 1A-1C for the semiconductor structure 100.1, FIGS. 2A-2C for the semiconductor structure 100.2, FIGS. 3A-3C for the semiconductor structure 100.3, FIGS. 4A-4B for the semiconductor structure 100.4 and FIGS. 5A-5C for the semiconductor structure 100.5). Formation of the metallic liner 129 can include deposition of one or more layers of metallic liner material including, for example, an adhesion material and a diffusion barrier material. The layers can be deposited, for example, by physical vapor deposition (PVD), sputtering, chemical vapor deposition (CVD), or any other suitable technique. In some embodiments, the layer of adhesion material could be, for example, a layer of titanium or tantalum and the layer of diffusion barrier material could be, for example, a layer of titanium nitride or tantalum nitride. Alternatively, any other metallic liner material(s) could be used for the metallic liner 129. It should be noted that, deposition of the metallic liner material into the via openings 182 will typically result in some amount of metallic liner material also being deposited into the cavity (e.g., aligned below the via openings, as illustrated).

The method can further include performing a deposition process to fill the cavity 180 and via openings 182 with a metallic fill material 126 in order to complete formation of a metallic heating element 120 and vias 123, respectively (see process 918 and FIGS. 1A-1C for the semiconductor structure 100.1, FIGS. 2A-2C for the semiconductor structure 100.2, FIGS. 3A-3C for the semiconductor structure 100.3, FIGS. 4A-4B for the semiconductor structure 100.4 and FIGS. 5A-5C for the semiconductor structure 100.5). In some embodiments, the metallic fill material 126 can be tungsten. Tungsten can be deposited by CVD from tungsten hexafluoride (WF₆). Alternatively, the metallic fill material could be a tungsten alloy. Alternatively, the metallic fill material 126 could be any other suitable metal or metal alloy fill material, which could be deposited through via openings into the cavity during processing and which exhibits suitable conductive-resistive properties such that, when a voltage differential at the vias 123 causes electric current to flow through the heating element 120, heat energy is generated (e.g., molybdenum or alloys thereof, nickel or alloys thereof, etc.). Those skilled in the art will recognizes that deposition techniques may vary depending upon the fill material. Furthermore, it should be noted that, depending upon the material being deposited, the deposition technique used, and the sizes of the cavity and via openings, one or more voids 128 (i.e., air or gas-filled bubble(s)) may be trapped within the metallic fill material 126, as illustrated. Additionally, it should be noted that the metallic fill material 126 deposited at process 918 can be either the same metal or metal alloy material or a different metal or metal alloy material used during subsequent BEOL processing to form metal wires or vias 198-199. For example, in some embodiments, the metallic fill material 126 can be a tungsten fill material and the adjacent metal wires and vias 198-199 could also be tungsten. In other embodiments, the metallic fill material 126 could be a tungsten fill material and the adjacent metal wires and vias 198-199 could be copper, aluminum, or any other metal material suitable for use in BEOL metal wires or vias. In any case, following deposition of the metallic fill material 126 at process 918, the resulting semiconductor structure 100.1, 100.2, 100.3, 100.4, or 100.5 will have a metallic heating element 120 with a first portion 120/(also referred to herein as a lower portion), which is seated in the first section 1801 of the cavity 180 adjacent to the semiconductor device 110 (i.e., in the MOL region 192), and with a second portion 120u (also referred to herein as an upper portion), which is seated within the second section 180u of the cavity 180 (i.e., in the BEOL region 193) and which has a tapered top end 120t (the shape of which is defined by the concave area 155 in the bottom surface of the additional dielectric layer 152).

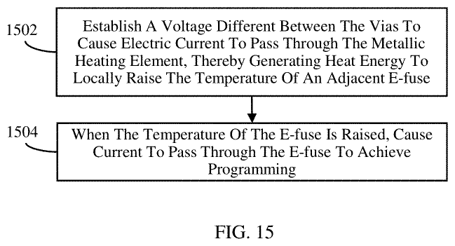

Also disclosed herein are methods for using a heating element, such as the heating element 120, in any of the semiconductor structures described above. For example, as mentioned above, in the semiconductor structures 100.1, 100.2, 100.3 or 100.4 described above and illustrated in FIGS. 1A-1C, 2A-2C, 3A-3C or 4A-4B, respectively, the semiconductor device 110 can be a polysilicon-based e-fuse and the heating element 120 could be employed to facilitate programming of that e-fuse. Specifically, referring to the flow diagram of FIG. 15, a method disclosed herein can include establishing a voltage differential across the vias 123 in order to cause electric current to pass through the metallic heating element 120, thereby generating heat energy that is sufficient to locally raise the temperature of the e-fuse (see process 1502). The method can further include, when the temperature of the e-fuse has been raised, connecting the anode 111 to a positive voltage source and the cathode 112 to a negative voltage source, thereby causing electric current to flow across the fuse link 113 from the anode 111 to the cathode 112 (see process 1504). Electric current flowing through the fuse link 113 in a high temperature environment can cause that fuse link 113 vary in structure, thereby increasing the resistance of the fuse link 113 from a first resistance level to a second resistance level that is greater than the first resistance level. For example, in the case of a salicide polysilicon fuse link, current can cause silicide migration resulting in an increase in resistance. In other polysilicon-based e-fuses, current can cause melting, agglomeration, etc. such that resistance is increased.

Also as mentioned above, in the semiconductor structure 100.5 described above and illustrated in FIGS. 5A-5C, the semiconductor device 110 can be a photonic or optical device, such as a ring resonator. In this case, a voltage differential can similarly be established across the vias 123 in order to cause electric current to pass through the metallic heating element 120, thereby generating heat energy that is sufficient to locally raise the temperature of a closed-curve waveguide 188 of the ring resonator. Such thermally tuning of the closed-curve waveguide 188 can be used to avoid temperature-dependent variations in the resonant wavelength.

By using a MOL metallic heating element 120 as disclosed herein to locally heat an e-fuse prior to programming, the amount of current needed to program the e-fuse is reduced and, thus, so is the amount of on-chip area-consuming support circuitry and current drivers. Furthermore, by using a MOL metallic heating element 120 as disclosed herein to locally heat any FEOL semiconductor device (e.g., an e-fuse, a close-curve waveguide of a ring resonator, etc.), the heating process is more efficient and reliable.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor device;
a dielectric layer on the semiconductor device; and
a metallic heating element having a first portion within the dielectric layer adjacent to the semiconductor device and a second portion extending from the first portion above the dielectric layer, wherein the second portion has a tapered end.

2. The structure of claim 1, further comprising an additional dielectric layer on the dielectric layer, wherein the metallic heating element comprises a metallic fill material within a cavity, wherein the cavity has a first section within the dielectric layer and a second section above the first section, wherein the cavity is capped by the additional dielectric layer, and wherein the tapered end of the second portion of the metallic heating element is seated within and immediately adjacent to a concave area in a bottom surface of the additional dielectric layer such that a shape of the tapered end is defined by a shape of the concave area.

3. The structure of claim 2, wherein the metallic fill material contains a void.

4. The structure of claim 2, wherein the metallic fill material comprises a metal or metal alloy.

5. The structure of claim 2, further comprising an etch stop layer between the dielectric layer and the additional dielectric layer.

6. The structure of claim 2, further comprising vias extending through the additional dielectric layer to the metallic heating element,
wherein the additional dielectric layer has via openings that extend to the cavity,
wherein the vias comprise a metallic liner lining the via openings and the metallic fill material further filling the via openings.

7. The structure of claim 6, wherein the metallic heating element further comprises at least some metallic liner material within the cavity.

8. The structure of claim 1,
wherein the metallic heating element is one of:
aligned above and parallel to the semiconductor device,
above, offset from, and parallel to the semiconductor device,
above and perpendicular to the semiconductor device, and
positioned laterally adjacent and parallel to the semiconductor device, and
wherein the metallic heating element is any of linear and curved, and
wherein the metallic heating element is adapted to pass heat energy to the semiconductor device.

9. The structure of claim 1, wherein the semiconductor device comprises any of an electronic fuse and a photonic device.

10. The structure of claim 1, further comprising multiple heating elements.

11. The structure of claim 1,
wherein the semiconductor device comprises a polysilicon electronic fuse,
wherein the metallic heating element comprises a tungsten heating element, and
wherein the dielectric layer comprises borophosphosilicate glass.

12. A method comprising:
forming a semiconductor device;
forming a dielectric layer on the semiconductor device; and
forming a metallic heating element having a first portion within the dielectric layer adjacent to the semiconductor device and a second portion extending from the first portion above the dielectric layer, wherein the second portion has a tapered end.

13. The method of claim 12,
wherein the forming of the metallic heating element comprises:
forming a trench in the dielectric layer extending toward the semiconductor device;
forming an additional dielectric layer on the dielectric layer over the trench, wherein the forming of the additional dielectric layer results in formation of a cavity with a first section in the dielectric layer and a second section above the first section, wherein the additional dielectric layer has a bottom surface and a portion the additional dielectric layer that caps the cavity has a concave area in the bottom surface;
forming via openings through the additional dielectric layer to the cavity; and
depositing a metallic fill material into the cavity to form the metallic heating element,
wherein the first portion of the metallic heating element is within the first section and the second portion of the metallic heating element is within the second section such that the tapered end of the second portion is seated within and immediately adjacent to the concave area and a shape of the tapered end is defined by a shape of the concave area, and
wherein the depositing of the metallic fill material further fills the via openings to form vias to the metallic heating element.

14. The method of claim 13, wherein a void forms within the metallic fill material during the depositing.

15. The method of claim 13, wherein the metallic fill material comprises a metal or metal alloy.

16. The method of claim 13, further comprising forming an etch stop layer between the dielectric layer and the additional dielectric layer.

17. The method of claim 13, further comprising, before the depositing of the metallic fill material, depositing a metallic liner to line at least the via openings.

18. The method of claim 17, wherein the depositing of the metallic liner results in at least some metallic liner material within the cavity.

19. The method of claim 12, wherein the forming of the semiconductor device comprises forming any of an electronic fuse and a photonic device.

20. A method comprising:
accessing a semiconductor structure comprising:
an electronic fuse;
a dielectric layer on the electronic fuse; and
a metallic heating element having a first portion within the dielectric layer adjacent to the electronic fuse and a second portion extending from the first portion above the dielectric layer, wherein the second portion has a tapered end; and
causing electric current to pass through the metallic heating element to generate heat energy sufficient to raise a temperature of the electronic fuse; and
when the temperature of the electronic fuse is raised, causing electric current to pass through the electronic fuse to achieve programming of the electronic fuse.
